(19) United States
(12) Patent Application Publication
(10) Pub. No.: US 2016/0259004 A1
(43) Pub. Date: Sep. 8, 2016

(54) DEBUGGER AND DEBUGGING SYSTEM

(71) Applicant: Advanced Digital Chips Inc., Gyeonggi-do (KR)

(72) Inventors: Soo Hyun Kum, Gyeonggi-do (KR); Sang Wan Kim, Gyeonggi-do (KR); Young Ho Cha, Gyeonggi-do (KR); Kwan Young Kim, Gyeonggi-do (KR); Byung Gueon Min, Gyeonggi-do (KR)

(21) Appl. No.: 14/669,087

(22) Filed: Mar. 26, 2015

(30) Foreign Application Priority Data
Mar. 5, 2015 (KR) 10-2015-0030910

(51) Int. Cl. G01R 31/317; G01R 31/3177

(52) U.S. Cl. CPC G01R 31/31705; G01R 31/31722; G01R 31/3177

(57) ABSTRACT

Provided is a debugging system including: a processor; and a debugger arranged between the processor and an external bus to determine whether or not an address of a job request including an instruction request or a data access request transferred from the processor to the external bus is hit on a preset address, wherein if the address of the job request is hit on the preset address, the debugger does not transfer the job request to the external bus, so that the processor is allowed to be stopped.

### CROSS-REFERENCE TO RELATED PATENT APPLICATION

This application claims the benefit of Korean Patent Application No. 10-2015-0030910, filed on Mar. 3, 2015 in the Korean Intellectual Property Office, the disclosure of which is incorporated herein in its entirety by reference.

### BACKGROUND OF THE INVENTION

1. Field of the Invention

The present invention relates to debugging logic, and more particularly, a debugger and a debugging system capable of analyzing a reason for an error occurring during program execution.

2. Description of the Related Art

In recent years, many debugging logics capable of analyzing a reason for an error occurring during program execution of a microprocessor or a reason for erroneous execution of a program have been widely used.

In the related art, a debugging logic is embedded in a microprocessor, and the debugging logic executes a debugging function. However, since the function of the debugging logic is very different from functions of the microprocessor, if the debugging logic is to be embedded in the microprocessor, the internal architecture of the microprocessor may be very complicated.

Therefore, in the related art, another debugging logic is operated with a configuration that the debugging logic is separately connected to an external bus as illustrated in FIG. 9. However, the debugging logic having such a configuration has a problem in that data coherence is not maintained according to a microprocessor or a problem in that a memory matching with a virtual address cannot be fetched.

### SUMMARY OF THE INVENTION

The present invention is to provide a debugger and a debugging system capable of reducing an intervention of a structure of a microprocessor.

The object of the present invention is not limited to the above-mentioned one, and other objects can be clearly understood from the following description by the ordinarily skilled in the art.

According to an aspect of the present invention, there is provided a debugging system including: a processor; and a debugger arranged between the processor and an external bus to determine whether or not an address of a job request including an instruction request or a data access request transferred from the processor to the external bus is hit on a preset address, wherein if the address of the job request is hit on the preset address, the debugger does not transfer the job request to the external bus, so that the processor is allowed to be stopped.

According to another aspect of the present invention, there is provided a debugger arranged between a processor and an external bus, including a determination unit which determines whether or not an address of a job request including an instruction request or a data access request transferred from the processor to the external bus is hit on a preset address, wherein if the address of the job request is hit on the preset address, the determination unit does not transfer the job request to the external bus, so that the processor is allowed to be stopped.

According to still another aspect of the present invention, there is provided a debugger including a determination unit which receives a to-be-executed instruction and an address of the to-be-executed instruction from a fetch unit and determines whether or not the address of the to-be-executed instruction is hit on a preset address, wherein if the address of the to-be-executed instruction is hit on the preset address, the determination unit does not transfer the to-be-executed instruction to a backend unit including a decoder and an execution unit, so that the fetch unit and the backend unit are allowed to be in a stopped state at the preset address.

According to the present invention, it is possible to reduce an intervention of a structure of a microprocessor by a debugger.

### BRIEF DESCRIPTION OF THE DRAWINGS

The above and other features and advantages of the present invention will become more apparent by describing in detail exemplary embodiments thereof with reference to the attached drawings in which:

FIG. 1 is a diagram illustrating a debugging system according to a first embodiment of the present invention;

FIG. 2 is a timing diagram illustrating a break process or a watch process by a debugger according to the first embodiment of the present invention;

FIG. 3 is a diagram for explaining problems during break execution in a pipeline structure;

FIG. 4 is a diagram illustrating instruction interface signals between a microprocessor and the debugger according to the first embodiment of the present invention;

FIG. 5 is a detailed diagram illustrating the debugger according to the first embodiment of the present invention;

FIG. 6 is a flowchart illustrating a break function execution method in the pipeline structure according to the first embodiment of the present invention;

FIG. 7 is a diagram illustrating interface signals during instruction request between the microprocessor and the debugger according to the first embodiment of the present invention;

FIG. 8 is a diagram illustrating a configuration of a debugger according to a second embodiment of the present invention; and

FIG. 9 is a diagram illustrating an interface of a debugger in the related art.

### DETAILED DESCRIPTION OF THE PREFERRED EMBODIMENTS

The above-described objects, other objects, advantages, and features of the present invention and methods achieving the objects will be clarified with reference to embodiments described in detail later together with the attached drawings. The present invention is not limited to the embodiments described later, but various different forms are available. The embodiments are provided in order to more clearly disclose the present invention and to clarify the scope of the invention to the ordinary skilled in the related art. The present invention is defined by only the claims. On the other hand, terms used in the application are used for explaining only specific embodiments, which are not intended to limit the present invention. In the specification, singular expression includes plural expressions if it does not have explicitly different meanings in context. Components, steps, operations, and/or elements associated with the terms “to comprise” and/or “comprising” used in this specification are not intended to exclude existence or addition of one more other components, steps, operations, and/or elements.

Hereinafter, embodiments of the present invention will be described in detail with reference to the attached drawings.

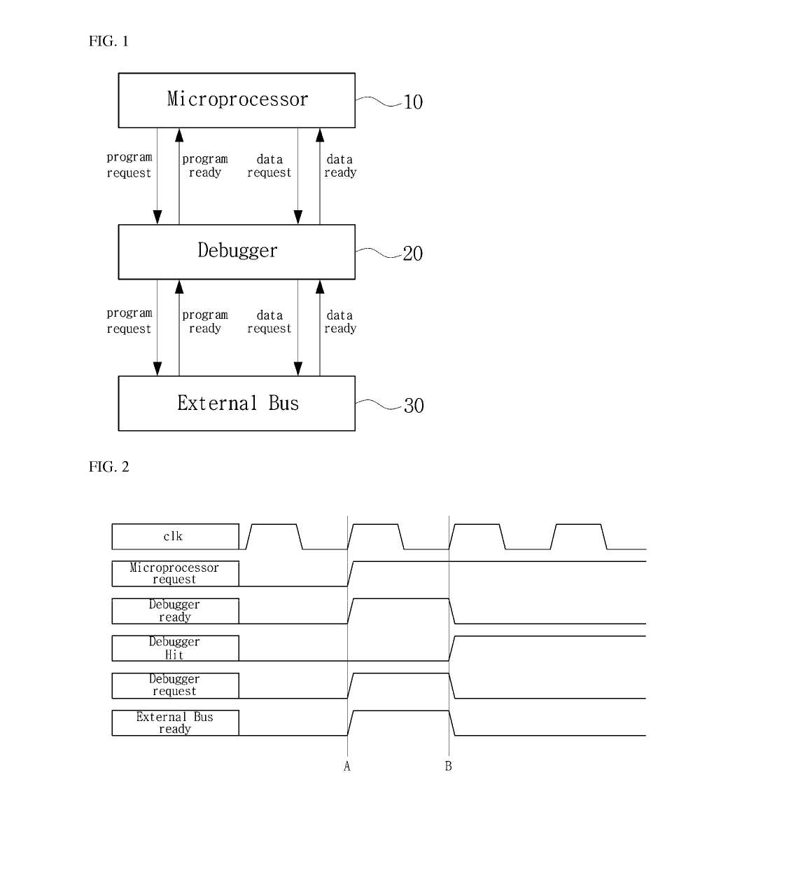

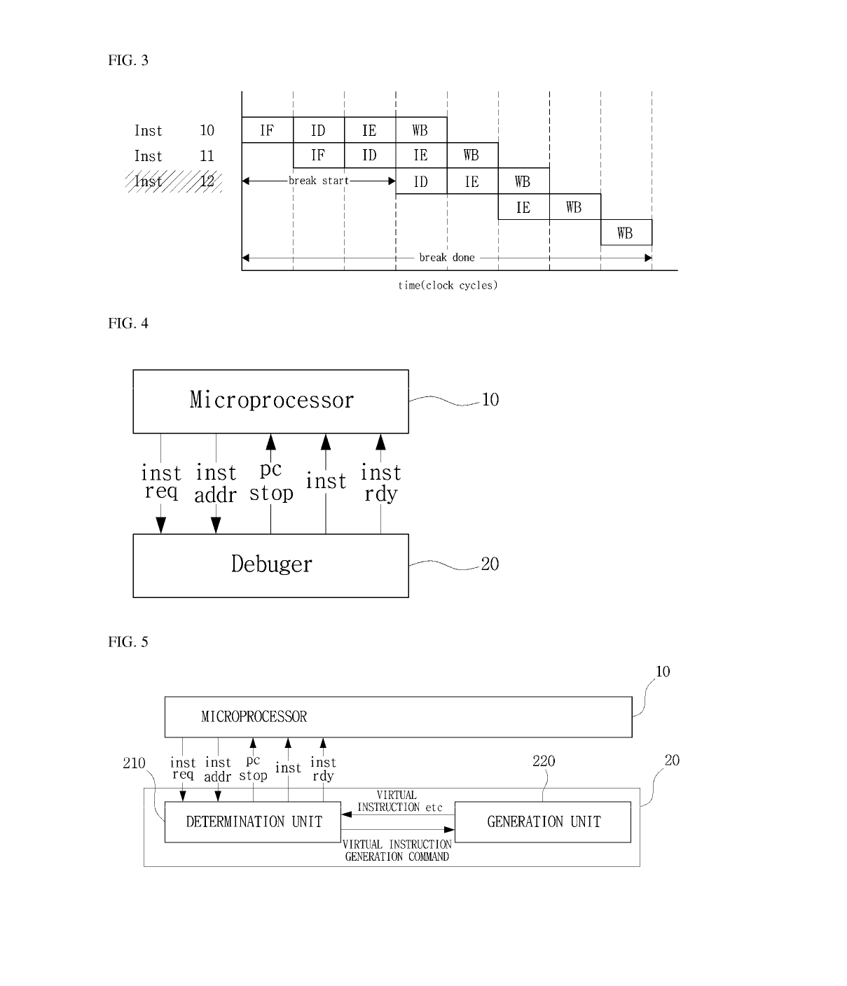

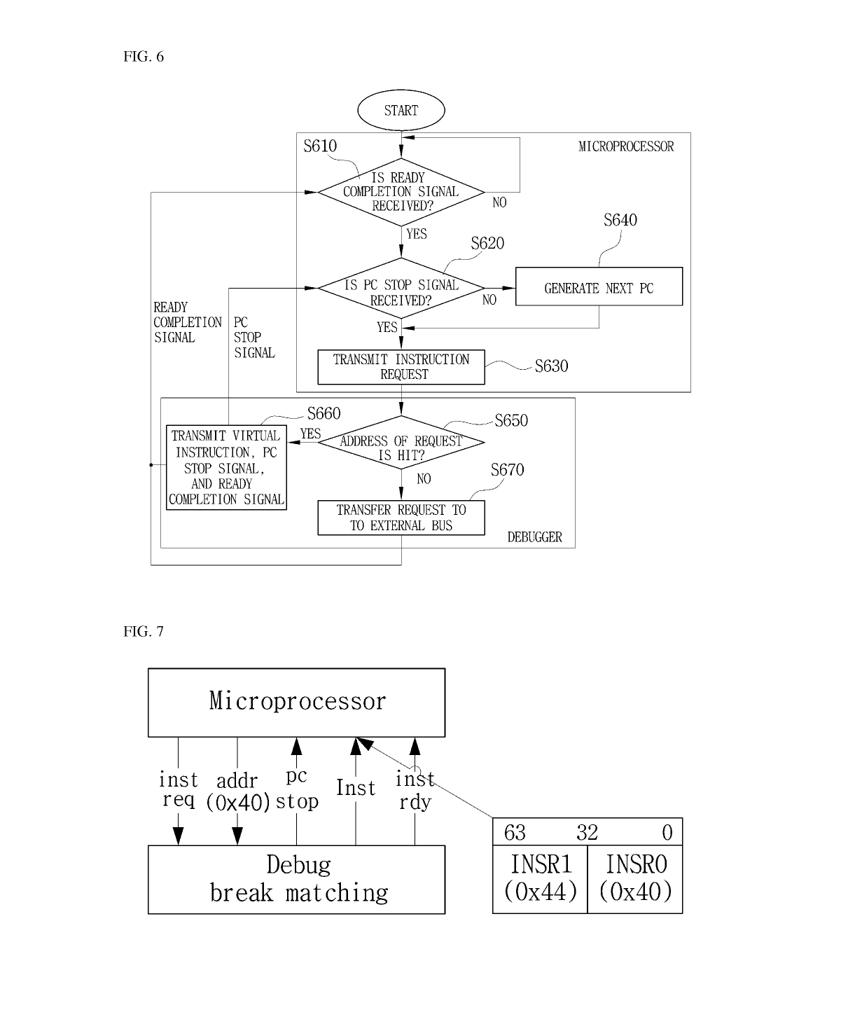

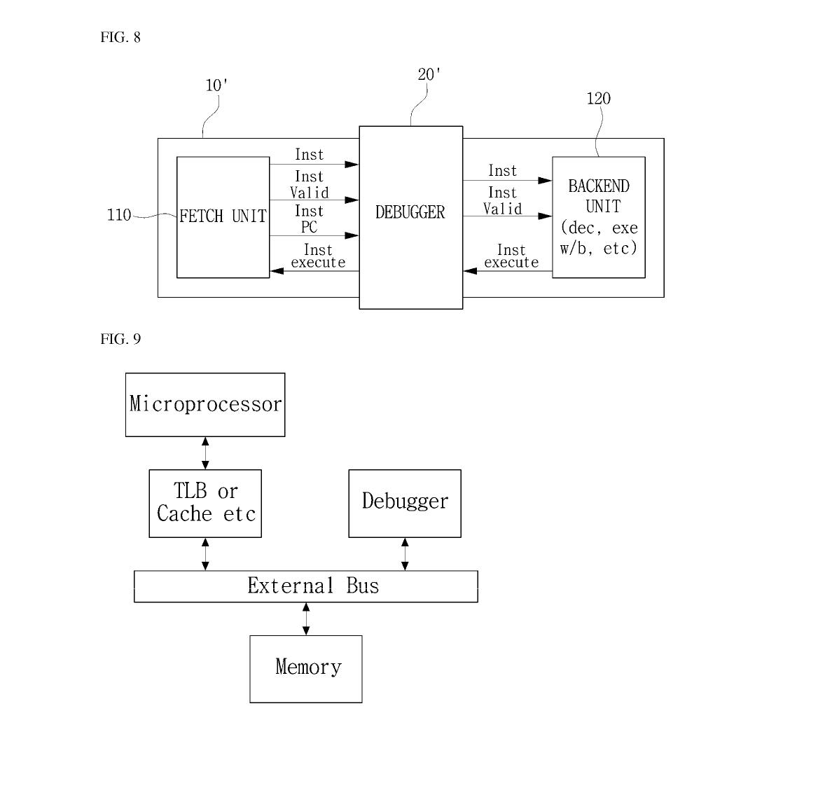

FIG. 1 is a diagram illustrating a debugging system according to a first embodiment of the present invention, and FIG. 2 is a timing diagram illustrating a break process or a watch process by a debugger according to the first embodiment of the present invention. FIG. 3 is a diagram for explaining problems during break execution in a pipeline structure, and FIG. 4 is a diagram illustrating instruction interface signals between a microprocessor and the debugger according to the first embodiment of the present invention. FIG. 5 is a detailed diagram illustrating the debugger according to the first embodiment of the present invention.

As illustrated in FIG. 1, the debugging system according to the first embodiment of the present invention is configured to include a microprocessor 10 and a debugger 20. Herein, the microprocessor 10 may include different types of processing units such as a central processing unit (CPU), a microcontroller unit (MCU).

The debugger 20 intercepts a job request including a program request (instruction request) and a data request which the microprocessor 10 transmits to an external bus 30. If a program (instruction) or data address (hereinafter, referred to an address of the job request) according to the job request is hit on a preset address, the debugger executes a break function or a watch function. Herein, a program memory may be connected to the external bus.

The break function is a function of allowing the microprocessor 10 to stop at a specific address (PC address) of the program during program execution. In addition, the watch function is a function of allowing the microprocessor 10 to stop if it is determined that there is an access to a specific data address during data access.

As a reference, a process (instruction fetch) of the microprocessor fetching an instruction for program execution is as follows.

Request the program memory to transmit an instruction (request)

If the instruction is ready, the program memory transmits a ready signal (hereinafter ready complete signal).

If the ready complete signal is received, the instruction fetch is completed.

Execute a next pipeline such as decode and execute.

In addition, processes of the microprocessor accessing a data area and fetching data are as follows.

Data Access Request (Request)

Data Access Completion (Ready)

If the ready complete signal is true, it is determined that the memory access is completed.

If the ready complete signal is false, a stall state where the next instruction is not in progress is formed.

(1) In the case where the microprocessor does not have a pipeline structure.

In the case where the break function by the debugger 20 is executed during an instruction or data fetch process, a timing diagram of signals transmitted and received among the microprocessor 10, the debugger 20, and the external bus 30 is the same as that of FIG. 2.

Similarly to FIG. 2, the microprocessor 10 transmits the job request (microprocessor request) including the program instruction or the data access request in synchronization with a rising edge of a clock, and the job request is transferred through the debugger 20 to the external bus 30.

Like a time point A of FIG. 2, if the job request is not hit on the preset address, the debugger 20 bypasses transmission/reception signals between the microprocessor 10 and the external bus 30.

On the other hand, like a time point B of FIG. 2, if the job request is hit on the preset address (refer to a debugger hit signal), the debugger 20 does not transfer the job request received from the microprocessor 10 to the external bus 30, so that the microprocessor 10 may break.

In other words, the microprocessor 10 does not receive a ready completion signal according to the job request, so that the microprocessor is allowed to stop (break) at the preset address.

(2) In the case where the microprocessor has a pipeline structure

If the microprocessor 10 has a pipeline structure, there exists an instruction of which execution is in progress in the pipeline at the time of stop (break) according to the break function, and in this case, the microprocessor may not stop at a desired address. In order to prevent this problem, the microprocessor 10 executes the break function or the watch function using a virtual instruction.

More specifically, for example, as illustrated in FIG. 3, the debugger 20 determines that the address of an instruction 12 (Inst 12) is hit on the preset address, and the debugger executes the break function (break start). At this time, if there exist the instructions 10 and 11 which are executed in the pipeline, the instruction of which execution is in pipeline before the stoppage of the microprocessor 10 needed to be completed. However, since it cannot be known when the instructions 10 and 11 in the pipeline are to be completed due to the situation of the stall or the like, in the case of waiting for the execution completion of the instruction in the pipeline, the microprocessor 10 may not be stopped at a desired break point or a desired watch point (preset address).

In order to prevent this problem, in the case where the microprocessor 10 has a pipeline structure, when the debugger 20 according to the first embodiment of the present invention executes the break function, the debugger fills the pipeline with the virtual instructions to flush the pipeline.

More specifically, if the address of the job request is hit on the preset address, the debugger 20 transmits at least the virtual instructions of which the number corresponds to a depth of the pipeline and the ready completion signal generated by itself for the break function. For example, if the depth of the pipeline is 5 stages, the debugger 20 may generate a total of five virtual instructions.

In addition, since the PC of the microprocessor 10 is required not to be changed during the breaking process, the debugger 20 further transfers a PC stop signal for preventing the change of the PC of the microprocessor 10 to the microprocessor 10.

If the microprocessor 10 receives an instruction or a data ready completion signal, the microprocessor determines whether or not the PC stop signal is applied in order to determine whether or not the corresponding ready completion signal is a ready completion signal transmitted from the debugger 20. If it is determined that the PC stop signal is applied, the microprocessor 10 determines that the received instruction is a virtual instruction and may not generate a next to-be-executed address (next address) PC. At this time, the microprocessor 10 may flush the pipeline by executing the virtual instructions one by one.

Hereinafter, in the case where the microprocessor 10 has a pipeline structure, the instruction interface signals between the microprocessor 10 and the debugger 20 will be described with reference to FIG. 4.

As illustrated in FIG. 4, the instruction interface signals between the microprocessor 10 and the debugger 20 may include an instruction address (Inst addr), an instruction request (Inst req), an instruction (Inst), an instruction ready completion (Inst rdy) signal, and a PC stop signal. The debugger 20 transfers the instruction (virtual instruction), the instruction ready completion signal, and the PC stop signal to the microprocessor 10 in order to execute the break function.

Hereinafter, an internal configuration of the debugger 20 according to the first embodiment of the present invention will be described with reference to FIG. 5. As illustrated in FIG. 5, the debugger 20 according to the first embodiment of the present invention is configured to include a determination unit 210 and a generation unit 220.

The determination unit 210 intercepts the address of the job request transmitted from the microprocessor 10 and determines whether or not the address of the job request is hit on the preset address. Herein, the preset address may be an address for stopping (breaking or watching).

If the address of the job request is not hit on the preset address, the determination unit 210 bypasses the job request received/transmitted between the microprocessor 10 and the external bus 30, the instruction which is ready according to the job request, or the data and ready completion signals (Inst rdy and Data rdy).

On the other hand if the address of the job request is hit on the preset address, in order to execute the break function, the determination unit 210 does not transfer the job request to the external bus 30 but transmits the virtual instruction, the ready completion signal, and the PC stop signal generated by the generation unit 220 to the microprocessor 10.

The above-described determination unit 210 may include, as an internal component, a path switching unit which bypasses the signals transmitted and received between the microprocessor 10 and the external bus 30 or blocks transmission and reception of signals between the microprocessor 10 and the external bus 30 and transfers signals (PC stop signal, virtual instruction, and ready completion signal) generated by itself.

The generation unit 220 generates the virtual instructions of which the number is preset according to a command of the determination unit 210 and transfers the virtual instructions to the determination unit 210. Herein, the preset number of virtual instructions may be the number corresponding to the depth of the pipeline. For example, the PC stop signal may be a high signal. In a normal period, the debugger 20 outputs the PC stop signal having a low level. When the break function is executed, the debugger 20 may change the level of the PC stop signal into a high level. The generation unit 220 may generate the ready completion signal and the PC stop signal by itself. Herein, the ready completion signal and the PC stop signal may be generated by the determination unit 210.

In FIG. 5, the case where the debugger 20 is applied to the microprocessor 10 having a pipeline structure is exemplified. Unlike the above-described case, in the case where the debugger 20 is applied to the microprocessor 10 having no pipeline structure, when the break function or the watch function is executed, the PC stop signal and the ready completion signal are unnecessary, so that the generation unit 220 may be omitted. At this time, in the case where the address of the job request is the preset address, the determination unit 210 does not transfer the job request to the external bus 30, but it is in a waiting state.

Hereinafter, a break function execution method in the pipeline structure according to the first embodiment of the present invention will be described with reference to FIG. 6. FIG. 6 is a flowchart illustrating the break function execution method in the pipeline structure according to the first embodiment of the present invention.

Referring to FIG. 6, if the microprocessor 10 receives the instruction and the ready completion signal (Yes in S610), the microprocessor 10 determines whether or not the PC stop signal is applied (S620).

If the instruction ready completion signal and the PC stop signal are received together, the microprocessor 10 does not change the PC but transmits the instruction request with respect to the same instruction address (S630). In this case, since the debugger 20 receives the instruction address for breaking again, the debugger can execute the break function again.

On the other hand, if the PC stop signal is not applied and only the instruction ready completion signal is received, the microprocessor 10 generates a next address (PC) (S640) and sends the instruction request for the next address.

If the debugger 20 receives the instruction request from the microprocessor 10, the debugger determines whether or not the address according to the received instruction request is hit on the preset address (S650).

If it is determined that the address according to the received instruction request is hit on the preset address, in order to execute the break function, the debugger 20 generates the virtual instruction and transmits the virtual instruction, the ready completion signal and the PC stop signal which are generated by itself (S660).

On the contrary, if it is determined that the address according to instruction request is not hit on the preset address, the debugger 20 transfers the received instruction request to the external bus 30 and transfers the ready completion signal received from the external bus 30 to the microprocessor 10 (S670).

On the other hand, in FIG. 6, the break function execution method according to the first embodiment of the present invention is exemplified. Unlike the above-described case, during the watch function execution, if the data access request is hit on the preset address similarly to the case where the microprocessor 10 has no pipeline structure, the debugger 20 may execute the watch function without transferring the ready completion signal according to the job request.

In this manner, in the first embodiment of the present invention, the debugger is applied between the microprocessor and the external bus, so that a change in design of the microprocessor can be minimized.

Furthermore, in the first embodiment, it is possible to prevent the problems in the related art that data coherence is not maintained according to the microprocessor or a memory corresponding to a desired address cannot be fetched.

Moreover, in the first embodiment, in the case where the microprocessor has a pipeline structure, the microprocessor is allowed to be in a stopped state at a desired break or a watch point.

Hereinafter, a break function in the case where a size of an instruction used in a system is not hit on a size of fetch bits of a microprocessor (the number of bits of an external bus) will be described with reference to FIG. 7.

As illustrated in FIG. 7, in the case where the microprocessor 10 fetches instructions or data having a size of 64 bits in accordance with a 32-bit ISA standard, the microprocessor 10 can receive two or more instructions by one-time fetch.

In FIG. 7, if the current address is 0x40 and the address where the breaking is to be executed is 0x42, the breaking cannot be executed at a desired address. This case may occur when the size of the instruction on which the breaking is to be executed is 16 bits.

Hereinafter, a debugger according to a second embodiment of the present coping with this case will be described with reference to FIG. 8. FIG. 8 is a diagram illustrating a configuration of the debugger according to the second embodiment of the present invention.

As illustrated in FIG. 8, the debugger 20′ according to the second embodiment of the present invention is arranged between a fetch unit 110 and a backend unit 120 in a microprocessor 10′. Herein, the backend unit 120 may be a decoder, an execution unit, or the like.

The fetch unit 110 transfers to-be-executed instructions (Inst), an instruction execution request (Inst Valid), and addresses (Inst PC) of the to-be-executed instructions to the backend unit 120. At this time, since the fetch unit 110 transfers the to-be-executed instructions one by one to the backend unit 120, in the present invention, even in the case where the size of the to-be-executed instruction is different from the size of the external bus, the addresses of the instructions can be monitored.

The debugger 20′ determines whether or not the PC is hit on the preset address. If it is determined that the PC is hit on the preset address, the debugger generates virtual instructions of which the number corresponds to at least the depth of the pipeline. Herein, the size of the virtual instruction may correspond to the size of the instruction transferred from the fetch unit 110. For example, in the case where the size of the instruction output from the fetch unit 110 is 8 bits, the size of the virtual instruction may be 8 bits.

Next, the debugger 20′ transfers the virtual instructions and the instruction execution request to the backend unit 120. At this time, although the backend unit 120 decodes the virtual instructions, since the virtual instructions are not the instructions which are actually executed, the backend unit 120 may not transfer the instruction execution completion (Inst execute) to the debugger 20′. Therefore, the fetch unit 110 cannot transfer other instructions following the instruction which causes breaking, but the debugger 20′ can allow the microprocessor 10 to be in the stopped state.

On the contrary, in the case where the address of the to-be-executed instruction is not hit on the preset address, the debugger 20′ transfers the instructions and the instruction execution request received from the fetch unit 110 to the backend unit 120. In this case, the backend unit 120 executes the instructions according to a normal procedure and notifies the instruction execution completion as a result of the execution to the fetch unit 110.

An internal configuration of the above-described debugger 20′ may be the same as that of FIG. 5. The determination unit (not shown) determines whether or not the address of the to-be-executed instruction is hit on the preset address. The determination connects or disconnects a path between the fetch unit 110 and the backend unit 120. In addition, the generation unit 220 may generate the virtual instructions and the instruction execution request signal.

On the other hand, in the above-described example, the case where the debugger 20′ transfers the virtual instructions and the instruction execution request is exemplified. However, unlike this, the debugger 20′ may transfer only the virtual instructions. In this case, the backend unit 120 may determine based on the reception of the instruction execution request whether or not the currently received instruction is a virtual instruction. Therefore, if the backend unit 120 does not receive the instruction execution request, although the backend unit determines that the received instruction is a virtual instruction and executes the received instruction, the backend unit may not transfer the execution completion signal associated with the virtual instruction. In addition, in the case where the microprocessor 10 has no pipeline structure, if the PC is hit on the preset address, the debugger 20′ may not transfer any instruction to the backend unit 120. In this case, the backend unit 120 waits for the instruction to be in the stopped state, and the fetch unit 110 does not receive the instruction execution completion signal to be in the stopped state.

On the other than, the above-described second embodiment is a configuration for the break function. It should be noted that a configuration for the watch function may be implemented by employing at least a portion of the configuration according to the first embodiment of the present invention. Specifically, for the watch function, the debugger 20′ is required to monitor the address of the data access request between the microprocessor 10 and the external bus 30. More specifically, the debugger 20′ intercepts the data access request transferred from the fetch unit 110 to the external bus 30 and determines whether or not the address of the data access request is hit on the preset watch address. If it is determined that the address of the data access request is hit on the preset watch address, the debugger 20′ does not allow the data access request to be transferred to the external bus, so that the debugger 20′ can execute the watch function.

In this manner, in the embodiment of the present invention, the break function can be simply executed by monitoring the instruction and the address of the instruction transferred from the fetch unit to the backend unit, so that it is possible not to greatly increase complexity of the microprocessor even though the debugger 20′ is included in the microprocessor.

While the present invention has been particularly shown and described with reference to exemplary embodiments thereof, it will be understood by those skilled in the art that various changes in form and details may be made therein without departing from the spirit and scope of the present invention as defined by the appended claims.

What is claimed is:

1. A debugging system comprising:
a processor; and
a debugger arranged between the processor and an external bus to determine whether or not an address of a job request including an instruction request or a data access request transferred from the processor to the external bus is hit on a preset address, wherein if the address of the job request is hit on the preset address, the debugger does not transfer the job request to the external bus, so that the processor is allowed to be stopped.

2. The debugging system according to claim 1, wherein if the processor has a pipeline structure, the debugger generates a plurality of virtual instructions corresponding to at least a depth of the pipeline which is of a no-operation (NOP) type and sequentially transmits a plurality of virtual ready completion signals including the respective virtual instructions to allow the pipeline to be in an execution completion state.

3. The debugging system according to claim 2,
wherein the debugger further transfers a PC (program counter) stop signal for stopping the processor from generating a PC together with the respective virtual ready completion signal, and
wherein if the processor receives the PC stop signal, the processor stops generating the PC for a next execution address and re-transmits the job requests of which the number corresponds to the depth of the pipeline to the debugger.

4. The debugging system according to claim 1, wherein if the address of the job request is not hit on the preset address, the debugger transfers the job request to the external bus and receives a ready completion signal which is a response signal according to the job request from the external bus to transfer the ready completion signal to the processor.

5. A debugger arranged between a processor and an external bus, comprising a determination unit which determines whether or not an address of a job request including an instruction request or a data access request transferred from the processor to the external bus is hit on a preset address, wherein if the address of the job request is hit on the preset address, the determination unit does not transfer the job request to the external bus, so that the processor is allowed to be stopped.

6. The debugger according to claim 5, further comprising a generation unit which generates a plurality of virtual instructions corresponding to at least a depth of the pipeline which is of a no-operation (NOP) type according to a command of the determination unit if the job request is an instruction request and the processor has a pipeline structure,
wherein the determination unit transfers the virtual instructions to the pipeline of the processor to allow the processor to be in an execution completion state.

7. The debugger according to claim 6,
wherein the generation unit further generates a PC stop signal for stopping the processor from generating a PC (program counter) and a ready completion signal, and
wherein the determination unit transfers the virtual instructions, the PC stop signal, and the ready completion signal to the processor.

8. The debugger according to claim 5, wherein if the address of the job request is not hit the preset address, the determination unit transfers the job request to the external bus and receives a ready completion signal which is a response signal according to the job request from the external bus to transfer the ready completion signal to the processor.

9. A debugger comprising a determination unit which receives a to-be-executed instruction and an address of the to-be-executed instruction from a fetch unit and determines whether or not the address of the to-be-executed instruction is hit on a preset address, wherein if the address of the to-be-executed instruction is hit on the preset address, the determination unit does not transfer the to-be-executed instruction to a backend unit including a decoder and an execution unit, so that the fetch unit and the backend unit are allowed to be in a stopped state at the preset address.

10. The debugger according to claim 9, further comprising a generation unit which generates a plurality of virtual instructions corresponding to a depth of a pipeline which is of a no-operation (NOP) type if the address of the to-be-executed instruction is hit on the preset address,
wherein the determination unit transfers the virtual instructions one by one instead of the to-be-executed instruction.

11. The debugger according to claim 9, wherein the determination unit intercepts a data access request transferred from the fetch unit to an external bus, determines whether or not an address of the data access request is hit on another preset address, and allow the data access request not to be transferred to the external bus if the address of the data access request is hit on another preset address.
